(19) United States
(12) Patent Application Publication
(10) Pub. No.: US 2011/0290314 A1
(43) Pub. Date: Dec. 1, 2011

(54) LIGHT SCATTERING ARTICLES USING HEMISPHERICAL PARTICLES

(76) Inventors: Andrey Kobyakov, Painted Post, NY (US); Aramais Zakharian, Painted Post, NY (US)

(21) Appl. No.: 13/088,831

(22) Filed: Apr. 18, 2011

Related U.S. Application Data
(60) Provisional application No. 61/349,542, filed on May 28, 2010.

(51) Int. Cl. H01L 31/0236

(52) U.S. Cl. 136/256

(57) ABSTRACT

Light scattering articles comprising inorganic substrates having textured surfaces utilize hemispherical inorganic particles having average diameters of 300 nm or less. The articles have an enhanced absorption at wavelengths in the range of from 400 nm to 600 nm and can be used in photovoltaic devices.

This application claims the benefit of priority to U.S. Provisional Application No. 61/349542 filed on May 28, 2010.

### BACKGROUND

1. Field

Embodiments relate generally to light scattering articles and more particularly to light scattering inorganic articles having textured surfaces comprising hemispherical particles useful for, for example, photovoltaic cells.

2. Technical Background

For thin-film silicon photovoltaic solar cells, light must be effectively coupled into the silicon layer and subsequently trapped in the layer to provide sufficient path length for light absorption. A path length greater than the thickness of the silicon is especially advantageous at longer wavelengths where the silicon absorption length is typically tens to hundreds of microns. Light is typically incident from the side of the deposition substrate such that the substrate becomes a superstrate in the cell configuration. A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode.

Amorphous silicon absorbs primarily in the visible portion of the spectrum below 700 nanometers (nm) while microcrystalline silicon absorbs similarly to bulk crystalline silicon with a gradual reduction in absorption extending to ˜1200 nm. Both types of material benefit from textured surfaces. Depending on the size scale of the texture, the texture performs light trapping and/or reduces Fresnel loss at the Si/substrate interface.

It would be advantageous to have light scattering inorganic articles wherein hemispherical particles create a textured surface on the substrate. Further, it would be advantageous to have light scattering inorganic articles with an enhanced absorption in the range of from 400 nm to 600 nm wavelengths for photovoltaic devices.

### SUMMARY

Light scattering inorganic articles, as described herein, address one or more of the above-mentioned disadvantages of conventional light scattering articles and may provide one or more of the following advantages: enhanced light trapping or light absorption at 400 nm-600 nm wavelengths, and several methods can be used to make the articles.

One embodiment is a light scattering article comprising an inorganic substrate having a textured surface, wherein the surface comprises hemispherical inorganic particles having an average diameter of 300 nm or less, and wherein the article has an enhanced absorption at wavelengths in the range of from 400 nm to 600 nm.

Another embodiment is a photovoltaic device comprising a light scattering article comprising an inorganic substrate having a textured surface, wherein the surface comprises hemispherical inorganic particles having an average diameter of 300 nm or less, and wherein the article has an enhanced absorption at wavelengths in the range of from 400 nm to 600 nm.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is a yz-cross-section of a conventional a-Si photovoltaic cell using a non-textured flat glass substrate.

FIG. 2 is a cross-section of features of an a-Si photovoltaic cell comprising a light scattering article having a textured glass surface comprising hemispherical glass particles randomly distributed on a glass surface, according to one embodiment.

FIGS. 3A and 3B show optical constants of the a-Si photovoltaic cell materials used in the simulations.

FIG. 4 shows the absorption efficiency computed for the conventional non-textured flat glass substrate cells shown in FIG. 1 and for the textured glass substrate cells with periodic and random distributions of hemispherical particles, according to some embodiments.

FIG. 5 shows the absorption efficiency computed for the conventional non-textured flat glass substrate cells and for the textured glass substrate cells with periodic distributions of hemispherical particles and aluminum back-reflector, according to some embodiments.

FIG. 6 shows the reflectivity spectra of a TCO/a-Si interface textured by periodic distribution of d=100-300 nm hemispherical particles, according to some embodiments.

FIG. 7 shows the absorption efficiency of the conventional non-textured flat glass substrate cells and non-conformal textured glass substrate cells with periodic distributions of hemispherical particles and silver back-reflector, according to some embodiments.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

One embodiment is a light scattering article comprising an inorganic substrate having a textured surface, wherein the surface comprises hemispherical inorganic particles having an average diameter of 300 nm or less, and wherein the article has an enhanced absorption at wavelengths in the range of from 400 nm to 600 nm.

In one embodiment, the enhanced absorption is 5 percent or more as compared to a non-textured substrate.

According to one embodiment, the substrate is planar.

The substrate can comprise a material selected from a glass, a ceramic, a glass ceramic, sapphire, silicon carbide, a semiconductor, and combinations thereof.

The particles can comprise a material selected from a glass, a ceramic, a glass ceramic, sapphire, silicon carbide, a semiconductor, metal oxides, and combinations thereof.

In one embodiment, the particles have an average diameter in the range of from 200 nm to 300 nm.

In some embodiments, the majority of the particles touch another particle. In some embodiments the majority of the particles overlap another particle.

Another embodiment is a photovoltaic device comprising a light scattering article comprising an inorganic substrate having a textured surface, wherein the surface comprises hemispherical inorganic particles having an average diameter of 300 nm or less, and wherein the article has an enhanced absorption at wavelengths in the range of from 400 nm to 600 nm.

The photovoltaic device can be, for example, an a-Si photovoltaic device or, for example, a thin film silicon tandem photovoltaic device.

In the device, in one embodiment, the enhanced absorption is 5 percent or more as compared to a non-textured substrate.

In the device, in one embodiment, the enhanced absorption is 5 percent or more as compared to a non-textured substrate.

In the device, in one embodiment, the substrate can be planar.

In the device, in one embodiment, the substrate can comprise a material selected from a glass, a ceramic, a glass ceramic, sapphire, silicon carbide, a semiconductor, and combinations thereof.

In the device, in one embodiment, the particles can comprise a material selected from a glass, a ceramic, a glass ceramic, sapphire, silicon carbide, a semiconductor, metal oxides, and combinations thereof.

In the device, in one embodiment, the particles have an average diameter in the range of from 200 nm to 300 nm.

In the device, according to some embodiments, the majority of the particles touch another particle.

In the device, according to some embodiments, the majority of the particles overlap another particle.

The device, according to one embodiment, further comprises a conductive material adjacent to the particles; and an active photovoltaic medium adjacent to the conductive material. The conductive material can be a transparent conductive film.

In one embodiment, the transparent conductive film comprises a textured surface. In one embodiment, the texture of the film is aligned with the texture of the surface. In another embodiment, the texture of the film is offset from the texture of the surface.

The active photovoltaic medium, according to one embodiment, is in physical contact with the transparent conductive film.

The device, according to one embodiment, comprises a counter electrode in physical contact with the active photovoltaic medium and located on an opposite surface of the active photovoltaic medium as the conductive material.

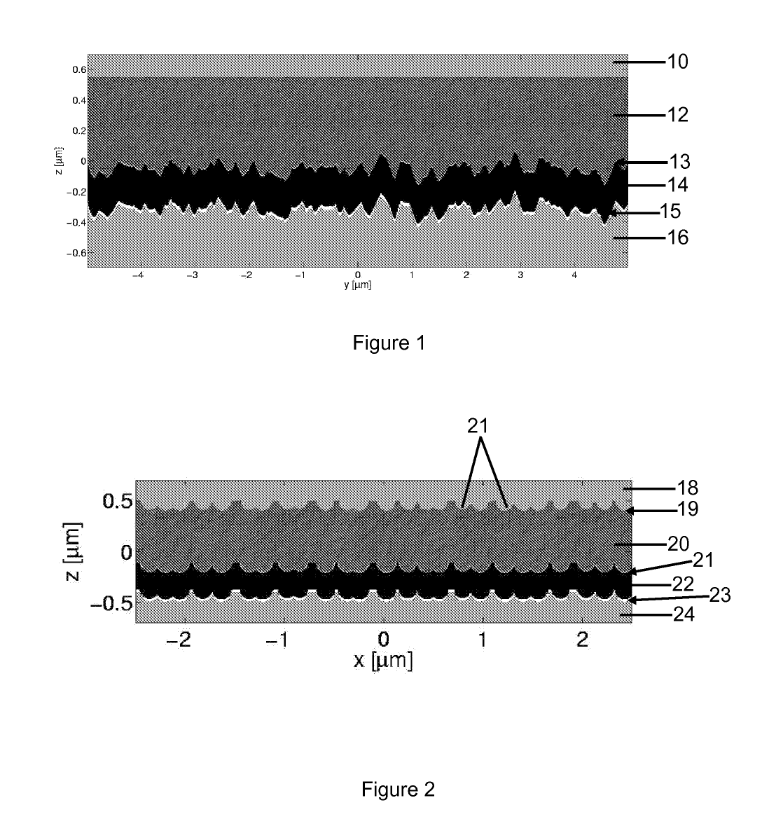

A cross-section of the three-dimensional geometry of features of a typical amorphous silicon (a-Si) cell based on a flat glass substrate 10 is shown in FIG. 1. The cell has a transparent conductive oxide (TCO) layer 12, for example, zinc oxide (ZnO) disposed on the flat glass substrate; a p a-Si, i a-Si, n a-Si (pin) junction (13, 14, 15, respectively); and a back-reflector 16 such as aluminum (Al). The RMS of the roughness of the TCO layer is 35 nm, maximum roughness height is 200 nm, and the correlation radius is 140 nm, with a Gaussian correlation function.

A cross-section of the three-dimensional geometry of features of a photovoltaic device, an amorphous silicon (a-Si) cell, in this embodiment, comprising a light scattering article comprising an inorganic substrate 18 having a textured surface 19, wherein the surface comprises hemispherical inorganic particles 21 having an average diameter of 300 nm or less, and wherein the article has an enhanced absorption at wavelengths in the range of from 400 nm to 600 nm is shown in FIG. 2. The inorganic particles such as hemispherical glass particles can be randomly distributed on a flat glass surface according to some embodiments. The light scattering articles can be made by several methods. For example, spherical particles can be deposited on a flat glass substrate using a process in which the particles initially are floated on the surface of a fluid and are subsequently transferred onto the flat substrate that is partially immersed in the fluid and is gradually drawn out. The resulting substrate is populated with particles, and is heated to sink the particles partway into the substrate, to obtain, for example, a substrate with hemispherical particle texture. The cell has a transparent conductive oxide (TCO) layer 20, for example, zinc oxide (ZnO) disposed on the flat glass substrate; a p a-Si, i a-Si, n a-Si (pin) junction (21, 22, 23 respectively); and a back-reflector 24 such as aluminum (Al). The transparent conductive oxide (TCO) and subsequent layers are conformal to the textured surface (hemispherical particles in this example) of the glass substrate, in one embodiment. That is, the subsequent layers can mirror the texture of the textured surface of the light scattering article.

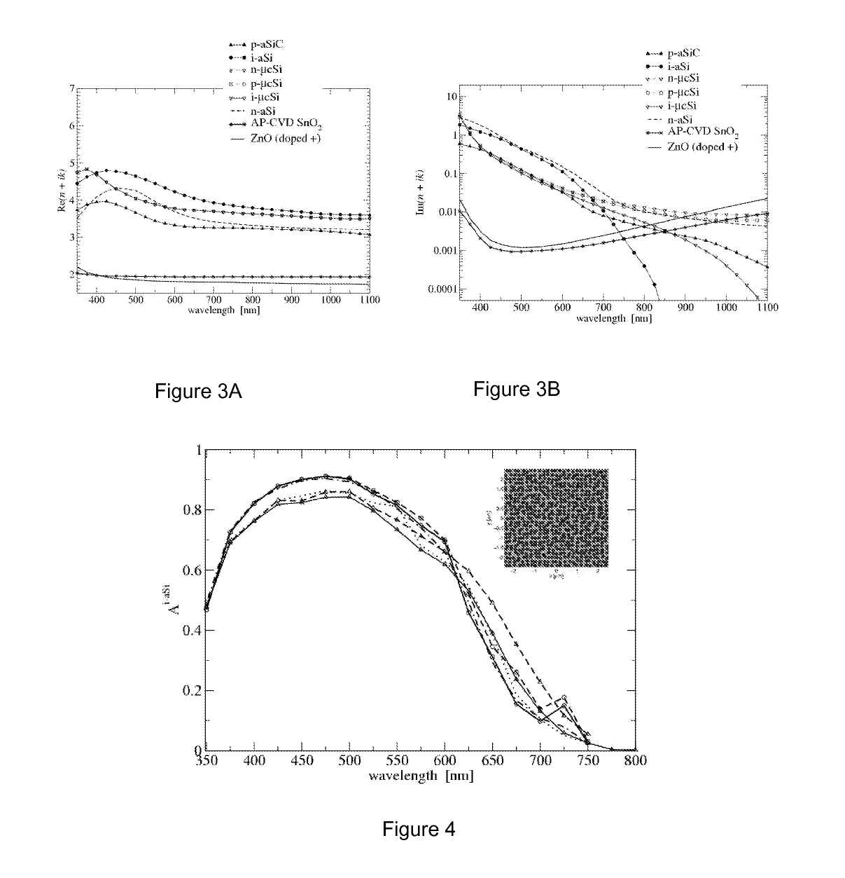

All simulated a-Si cells have the same material optical constants, as shown in FIG. 3A and FIG. 3B, and layer thicknesses as the conventional non-textured flat glass substrate cell used for comparison. For the materials that are used in depositing the cell layers, FIG. 3A shows the real part of the complex-valued optical index of refraction as a function of the wavelength. The corresponding imaginary part, responsible for absorption of light in the material, is shown in FIG. 3B.

For simulations, a full vectorial, three dimensional (3D) Finite-Difference Time-Domain (FDTD) approach was utilized. The FDTD method directly solves Maxwell's equations in the time domain without any simplifying assumptions and is regarded as one of the most reliable and accurate numerical methods. Since the 3D problem requires a significant Central Processing Unit (CPU) time, the task was parallelized on 32-64 processors of the multi-processor cluster. In FDTD simulations, the optical absorption efficiency of the cell is evaluated by directly computing the integral of the divergence of the Poynting vector (<div S>) over the volume of the intrinsic a-Si absorbing layer.

FIG. 4 shows the absorption efficiency (normalized to the energy flux incident from the glass) for the conventional non-textured flat glass substrate cells and for the proposed textured glass cells with periodic and random distributions of hemispherical particles. Solid and dashed lines correspond to the cells with aluminum and silver back-reflectors, respectively. The inset shows a sample xy cross-section of the random distribution of 200 nm diameter particles (the corresponding xz cross-section is shown in FIG. 2). In textured glass cells with either Al or Ag back-reflector, the optical absorption is higher by 5-10% for the wavelength band 400-600 nm. This results in a 4.3% increase in the maximum achievable current density (MACD), when absorptance is integrated over the a-Si absorption band 350 nm-750 nm, weighted with the standard AM1.5 solar spectrum. The spectral position of the enhancement at λ=725 nm does not depend strongly on the back-reflector material (Al vs Ag), and therefore likely it is not due to the plasmon resonance. It is reduced or disappears when there is no periodicity in the particle distribution, due to either random x,y positions of 200 nm particles in FIG. 4, or due to both random positions and random variation in the particle diameter in FIG. 4. The enhancement at short wavelengths is not affected by random positioning of uniform 200 nm particles, but the improvement in the absorption is smaller for the random distribution with particle size dispersion.

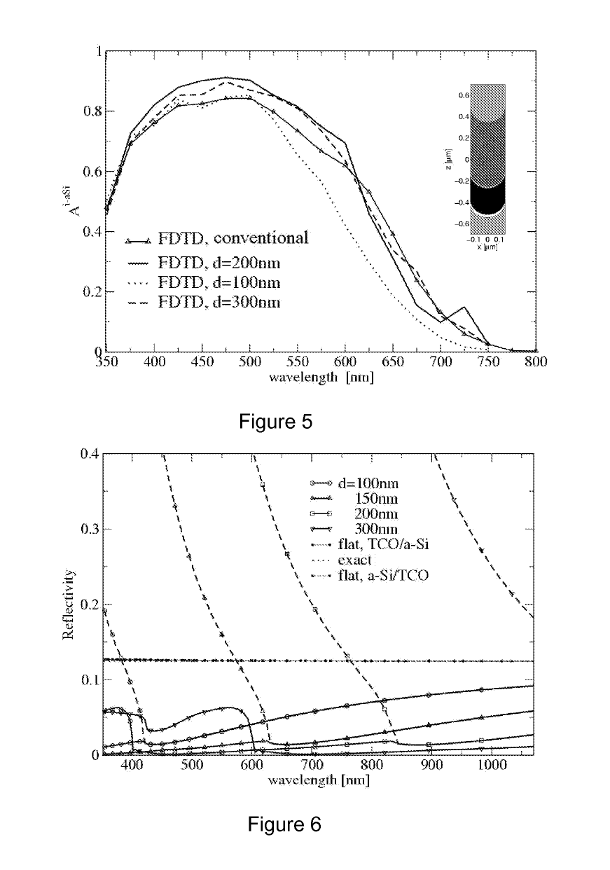

To evaluate the effect of the particle size on the textured cell efficiency, optical absorption was computed in cells with hemispherical particle diameters d=100-300 nm (FIG. 5). Absorption efficiency is enhanced at short wavelengths for particles with d>100 nm. The maximum enhancement occurs for 200 nm diameter particles between λ=400 nm and 600 nm, and there is a tendency for larger particles to lead to larger absorption at long wavelengths, λ>650 nm, however, at the cost of the reduced absorption efficiency at shorter wavelengths.

Scattering properties of the textured surfaces at the interface between the TCO and silicon absorber were examined. FIG. 6 shows the reflectivity spectra of a TCO/a-Si interface textured by periodic distribution of d=100-300 nm hemispherical particles. To identify the dependence of the reflectivity solely on the particle size, spectrally flat dispersion is assumed in these computations (n_{TCO}=2, n_{a-Si}=4.18, representing TCO and intrinsic a-Si refractive indices at λ≈600 nm). The reflectivity for light incident from the TCO side (shown by solid lines in FIG. 6) is decreased, compared to the flat interface. This anti-reflection (AR) effect is most pronounced (strongly decreased reflectivity) and least wavelength dependent (in the 400-650 nm band) for d=200 nm particles. At the same time, the reflectivity of light incident from the a-Si side (dashed lines in FIG. 6) shows high reflectivity (HR effect) which is also largest for the d=200 nm textured interface. This combination of the low reflectivity for the incident light on its way to the absorbing silicon layer, and the high reflectivity for the light traveling in the opposite direction, leads to improved absorption efficiency due to light trapping in the silicon layer. Thus, the reflectivity spectra correlate well with the computed absorption efficiency shown in FIG. 5, in which the surface with 200 nm diameter particles also performs best in the λ=400 nm-600 nm spectral range.

The AR-HR effect at the textured interface between two dielectric media can be explained in the following way. Non-reversibility of the light propagation can take place for a particular type of surface roughness or pattern period. If the characteristic feature of the surface is small compared to a wavelength in a low index medium the random surface acts as a gradual transition layer between two media and the AR effect takes place. At the same time, if the surface features are large enough for the wavelength in the high-index medium, the geometrical optics ray picture explains the increased reflectivity in the high-to-low index direction. If the AR effect dominates in the low-to-high index direction and HR effect dominates in the opposite direction, the light trapping occurs. This effect can be recognized in FIG. 6.

In another embodiment, in the device, the texture of the film is offset from the texture of the surface. By shifting the particle distribution at the silicon-back-reflector interface by a half-period along the x- and y-axis, one can realize different layer geometry. With this non-conformal arrangement, larger enhancement in the absorption is achieved at short wavelengths for 200 nm particles. Increasing particle diameters to 300 nm red-shifts the maximum absorption efficiency, leading to a larger enhancement in the λ=525 nm to 625 nm band. The non-conformal geometry has the same amount of i-aSi material as the corresponding conformal arrangement. The absorption enhancement in the wavelength band 400-600 nm is thus improved to 10-15%, corresponding to ˜5% improvement in the MACD.

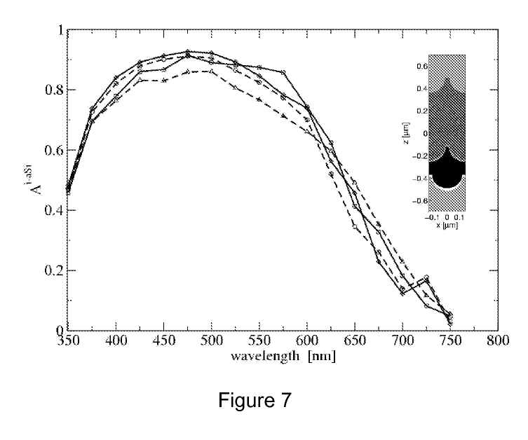

FIG. 7 shows absorption efficiency of conventional non-textured flat glass substrate cells and non-conformal textured glass substrate cells with periodic distributions of hemispherical particles and silver back-reflector. The inset shows an xz cross-section of the periodic distribution for d=300 nm particles.

From a set of our numerical simulations, the hemispherical particle diameters in the range of 200-300 nm were found to be optimal for creating light scattering articles having at least one textured surface and photovoltaic devices comprising the light scattering articles to achieve improved light absorption in a-Si cells within the 400-600 nm wavelength band.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A light scattering article comprising an inorganic substrate having a textured surface, wherein the surface comprises hemispherical inorganic particles having an average diameter of 300 nm or less, and wherein the article has an enhanced absorption at wavelengths in the range of from 400 nm to 600 nm.

2. The article according to claim 1, wherein the enhanced absorption is 5 percent or more as compared to a non-textured substrate.

3. The article according to claim 1, wherein the substrate is planar.

4. The article according to claim 1, wherein the substrate comprises a material selected from a glass, a ceramic, a glass ceramic, sapphire, silicon carbide, a semiconductor, and combinations thereof.

5. The article according to claim 1, wherein the particles comprise a material selected from a glass, a ceramic, a glass ceramic, sapphire, silicon carbide, a semiconductor, metal oxides, and combinations thereof.

6. The article according to claim 1, wherein the particles have an average diameter in the range of from 200 nm to 300 nm.

7. The article according to claim 1, wherein the majority of the particles touch another particle.

8. The article according to claim 1, wherein the majority of the particles overlap another particle.

9. A photovoltaic device comprising a light scattering article comprising an inorganic substrate having a textured surface, wherein the surface comprises hemispherical inorganic particles having an average diameter of 300 nm or less, and wherein the article has an enhanced absorption at wavelengths in the range of from 400 nm to 600 nm.

10. The device according to claim 9, wherein the enhanced absorption is 5 percent or more as compared to a non-textured substrate.

11. The device according to claim 9, wherein the substrate is planar.

12. The device according to claim 9, wherein the substrate comprises a material selected from a glass, a ceramic, a glass ceramic, sapphire, silicon carbide, a semiconductor, and combinations thereof.

13. The device according to claim 9, wherein the particles comprise a material selected from a glass, a ceramic, a glass ceramic, sapphire, silicon carbide, a semiconductor, metal oxides, and combinations thereof.

14. The device according to claim 9, wherein the particles have an average diameter in the range of from 200 nm to 300 nm.

15. The device according to claim 9, wherein the majority of the particles touch another particle.

16. The device according to claim 9, wherein the majority of the particles overlap another particle.

17. The device according to claim 9, further comprising
a conductive material adjacent to the particles; and
an active photovoltaic medium adjacent to the conductive material.

18. The device according to claim 17, wherein the conductive material is a transparent conductive film.

19. The device according to claim 18, wherein the transparent conductive film comprises a textured surface.

20. The device according to claim 19, wherein the texture of the film is aligned with the texture of the surface.

21. The device according to claim 19, wherein the texture of the film is offset from the texture of the surface.

22. The device according to claim 17, wherein the active photovoltaic medium is in physical contact with the transparent conductive film.

23. The device according to claim 17, further comprising a counter electrode in physical contact with the active photovoltaic medium and located on an opposite surface of the active photovoltaic medium as the conductive material.
